(19) United States
(12) Patent Application Publication
(10) Pub. No.: US 2022/0416098 A1
(43) Pub. Date: Dec. 29, 2022

(54) Light Receiving Element

(71) Applicant: Nippon Telegraph and Telephone Corporation, Tokyo (JP)

(72) Inventors: Shoko Tatsumi, Musashino-shi, Tokyo (JP); Masahiro Nada, Musashino-shi, Tokyo (JP)

(21) Appl. No.: 17/762,314

(22) PCT Filed: Oct. 15, 2019
(86) PCT No.: PCT/JP2019/040494

§ 371 Date: Mar. 21, 2022

(51) Int. Cl. H01L 31/0232; H01L 31/055

(52) U.S. Cl. CPC H01L 31/02327; H01L 31/055

(57) ABSTRACT

A light receiving element enables light incidence from the upper surface of a light receiving element while realizing a structure in which the optical path length is extended, and as a result, facilitates optical mounting. A light receiving element in which a first semiconductor layer, a light absorbing layer composed of a semiconductor, a second semiconductor layer, a first electrode formed in contact with the first semiconductor layer, and a second electrode formed in contact with the second semiconductor layer and including a first reflective layer composed of a metal are formed on an upper surface of a substrate, wherein incident light is incident from the upper surface of the substrate, reflected by the bottom surface of the substrate, and then incident on the light absorbing layer obliquely to the vertical direction.

### TECHNICAL FIELD

The present invention relates to a light receiving element, and more particularly to a semiconductor light receiving element capable of high-speed and high-sensitivity operation.

### BACKGROUND ART

Photodiodes are widely used elements as semiconductor light receiving elements for optical communication. A photodiode is an element that performs photoelectric exchange by generating electrons and holes when light is absorbed under irradiation with light having an energy equal to or higher than the band gap of a semiconductor. The most basic photodiode is called a pin photodiode and has a structure in which an i-layer having a low impurity density is sandwiched on both sides between p-type and n-type semiconductors doped with impurities to a high density. Where a reverse bias is applied to such pin structure, an electric field is generated in the i-layer, electrons and holes generated by light irradiation are swept, and a photocurrent is generated. The ratio of the number of carriers that contribute to the photocurrent to the number of incident photons is called external quantum efficiency, and it is essential to improve the external quantum efficiency in order to increase the sensitivity.

Extending an optical path length in a light absorbing layer is a means for improving the external quantum efficiency. The optical path length can be extended by thickening the light absorption layer, but if the light absorbing layer is thickened, the traveling time of the carriers increases and a high-speed response is hindered. Another method for extending the optical path length is to form a folded structure so that light passes through the light absorbing layer a plurality of times. A light receiving element described in NPL 1 has a structure in which a multilayer film is formed on a substrate, and light incident on the light receiving element is folded back by a multilayer film formed on the substrate side that is farther from the light absorbing layer. However, it is shown in NPL 1 that a reflectance of only about 70% can be obtained with the multilayer film. Further, since the multilayer film has a large wavelength dependence and it is necessary to optimize the multilayer film according to the wavelength band to be used, a complicated and precise layer structure is required according to the application.

Meanwhile, in the light receiving element described in PTL 1, a structure is used in which light is incident on the substrate from the side (the lower surface of the substrate) opposite to the side where the light absorbing layer is formed or from the side surface of the substrate, and the incident light is folded back by a mirror formed on the upper surface of the light receiving element. With the mirror, a reflectance (90% or more, see PTL 1) equal to or higher than that of the multilayer film can be obtained, the wavelength dependence is small, and the decrease in quantum efficiency due to the folded structure can be reduced.

However, the light receiving element in which the mirror is formed inevitably has a light incident structure (lower surface incident) in which the light passes through the substrate. In this case, a step of mirror polishing the semiconductor substrate is required, and an antireflection film is formed on the polished surface, which complicates the wafer process. Further, when mounting the produced light receiving element as a component of an optical receiver, it is necessary to mount the flip chip with the polished surface facing upward. Since such mounting requires a dedicated device, a heavy burden is placed on mounting.

Accordingly, a “waveguide type structure” has been proposed as a structure that easily realizes high sensitivity and increase in speed by contrast with the “vertical incidence structure” in which light is incident in a direction parallel to the stacking direction of semiconductor layers constituting a pin structure, that is, perpendicular to a substrate (for example, NPL 2).

However, with the waveguide type structure, processing is performed not only on the upper surface but also on the side surfaces, which makes it difficult to manufacture and evaluate at a wafer level. Further, since the area of the light incident surface is also much smaller than that of the vertically incident structure, the tolerance when mounting on an optical receiver is greatly deteriorated. Thus, in the related art, it is difficult to realize high-speed and high-sensitivity operation in a light receiving element while ensuring the ease of optical mounting and element fabrication.

### CITATION LIST

### Patent Literature

[PTL 1] Japanese Patent Application Publication No. 2011-187607.

### Non Patent Literature

[NPL 1] E. Ishimura, et al., “High efficiency 10 Gbps InP/lnGaAs Avalanche Photodiodes with Distributed Bragg Reflector”, Proc. 27th Eur. Conf. On Opt.
[NPL 2] K. Kato, et al., “110-GHz, 50%-Efficiency Mushroom-Mesa Waveguide p-i-n Photodiode for a 1.55- μm Wavelength”, IEEE Photon. Technol. Lett., Vol. 6, No. 6, Jun (1994).

### SUMMARY OF THE INVENTION

An object of the present invention is to provide a light receiving element that enables light incidence from the upper surface of a light receiving element while realizing a structure in which the optical path length is extended, and as a result, facilitates optical mounting.

n order to achieve such an object, in a light receiving element according to one embodiment of the present invention, a first semiconductor layer composed of a first conductive type semiconductor formed on an upper surface of a substrate, a light absorbing layer composed of a semiconductor, a second semiconductor layer composed of a second conductive type semiconductor, a first electrode formed in contact with the first semiconductor layer, and a second electrode formed in contact with the second semiconductor layer and including a first reflective layer composed of a metal are formed in the order of description in a vertical direction of the upper surface of the substrate, wherein incident light is incident from the upper surface of the substrate, reflected by the bottom surface of the substrate, and then incident on the light absorbing layer obliquely to the vertical direction.

### BRIEF DESCRIPTION OF DRAWINGS

FIG. 1 is a cross-sectional view showing the configuration of a semiconductor light receiving element according to the first embodiment of the present invention.

FIG. 2 is a diagram for explaining an angle design of an oblique surface of the semiconductor light receiving element of the first embodiment.

FIG. 3 is a diagram for explaining the propagation of light inside the semiconductor light receiving element of the first embodiment.

FIG. 4 is a diagram showing the upper surface and a cross section of the semiconductor light receiving element of the first embodiment.

FIG. 5 is a cross-sectional view showing the configuration of a semiconductor light receiving element according to the second embodiment of the present invention.

FIG. 6 is a cross-sectional view showing the configuration of a semiconductor light receiving element according to the third embodiment of the present invention.

### DESCRIPTION OF EMBODIMENTS

Hereinafter, embodiments of the present invention will be described in detail with reference to the drawings.

### First Embodiment

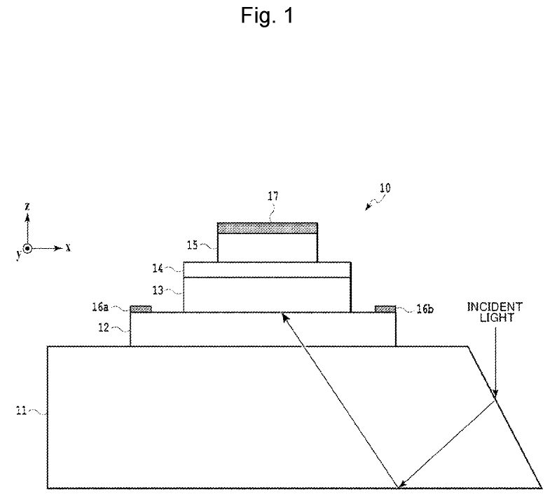

FIG. 1 shows the configuration of a semiconductor light receiving element according to the first embodiment of the present invention. In a semiconductor light receiving element 10, a first semiconductor layer 12 formed on the upper surface of a substrate 11 and composed of a first conductive type semiconductor, a light absorbing layer 13 composed of a semiconductor, an avalanche layer 14 composed of a semiconductor, and a second semiconductor layer 15 composed of a second conductive type semiconductor are formed in the order of description in a vertical direction (z-axis direction) on the upper surface of the substrate 11. In FIG. 1, the z-axis direction is a semiconductor crystal growth direction. An oblique surface (facet surface) for light incidence is formed on the side surface of the substrate 11.

Electrodes 16a and 16b are formed on the first semiconductor layer 12, and an electrode 17 is formed on the upper surface of the second semiconductor layer 15. The electrode 17 includes a reflective layer composed of a metal, and serves as a mirror formed on the surface above the light absorbing layer 13. The avalanche layer 14 may or may not be present, but where it is present, a higher light receiving sensitivity can be obtained. As long as the avalanche layer 14 is between the first semiconductor layer 12 and the second semiconductor layer 15, the avalanche layer may not be formed on the side of the electrode 17 with respect to the light absorbing layer 13.

The incident light is incident on the oblique surface of the substrate 11 in parallel with the z-axis, refracted on the oblique surface, reflected on the bottom surface of the substrate 11, and incident on the light absorbing layer 13 of the light receiving element 10. Therefore, the light incident on the light receiving element 10 is not parallel or perpendicular to the z-axis, but is incident obliquely with respect to the vertical direction of the substrate 11.

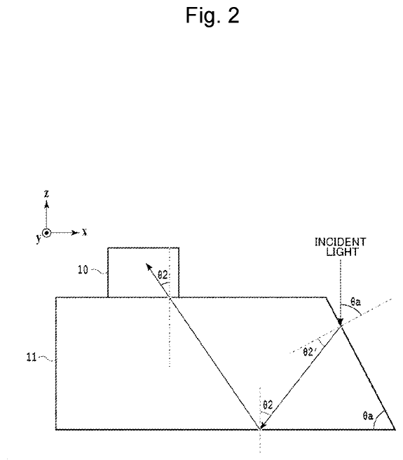

The angle design of the oblique surface of the semiconductor light receiving element of the first embodiment will be described with reference to FIG. 2. The beam size and element diameter are indispensable for the design to extend the optical path length. After designing these two parameters, the angle of the oblique surface of the substrate may be designed to determine the feasibility thereof. In the cross-sectional view of FIG. 2 (xz plane), the acute angle formed by the oblique surface and the bottom surface of the substrate 11 is defined as θₐ. At this time, the incident light parallel to the z-axis has an angle of incidence of θₐ with respect to the oblique surface of the substrate 11. The angle of incidence of the light folded back by the bottom surface of the substrate 11 on the light receiving element is defined as θ₂. The refraction angle θ₂ of the incident light is determined by Snell's law.

sinθₐ=n₂ sinθ′₂ Math. 1

n₂ is the refractive index of the substrate 11. Also, from the relationship of θ′₂+θ₂=θₐ, the relationship of

$$tan {θ}_{a} = {θ}_{2} ( \frac{{n}_{2}}{{n}_{2} cos {θ}_{2} - 1} ) \qquad Math . 2$$

holds based on the formula of the sum product of trigonometric functions.

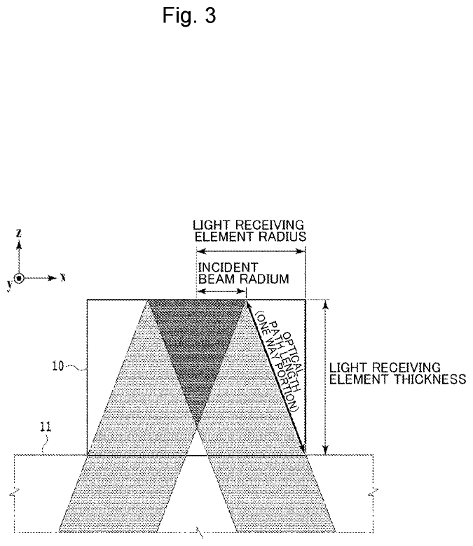

Referring to FIG. 3, the propagation of light inside the semiconductor light receiving element of the first embodiment will be described. The incident light folded back on the bottom surface of the substrate 11 is incident from the substrate 11 side of the light receiving element 10, passes through the light absorbing layer 13 of the light receiving element 10, and is folded back by the mirror on the upper surface. Since the optical path length L in the light receiving element at this time is twice the optical path from the upper surface of the substrate 11 to the upper surface of the light receiving element 10, the optical path length L is determined by

$$L = 2 \sqrt{{( Light receiving element radius - Incident beam radius )}^{2} + {( Light receiving element thickness )}^{2}} \qquad Math . 3$$

From the propagation of light, the beam diameter ω(z) at a distance z away from the beam waist is expressed by the following formula.

$$ω ( z ) = {ω}_{0} \sqrt{1 + {( \frac{λ z}{n {πω}_{0}} )}^{2}} \qquad Math . 4$$

n is the refractive index of the medium through which the light passes, λ is the wavelength of light, and ω₀ is the beam waist diameter. When the incident light is in focus on the light receiving element 10, where the size of the beam propagating in the thickness direction of the light receiving element and the beam waist are substantially the same, the incident beam diameter may be regarded as substantially the beam waist.

Depending on the angle θ₂ of incidence of light on the light receiving element 10 and the refractive index of the medium under the substrate 11, the light can propagate to the medium under the substrate 11 without total reflection by the substrate. Assuming that the refractive index of the medium under the substrate 11 is n_{b}, total reflection occurs when

n_{b}≤n₂ sinθ₂ Math. 5

Where the material under the substrate 11 is glass or air, the above conditions for total reflection are satisfied.

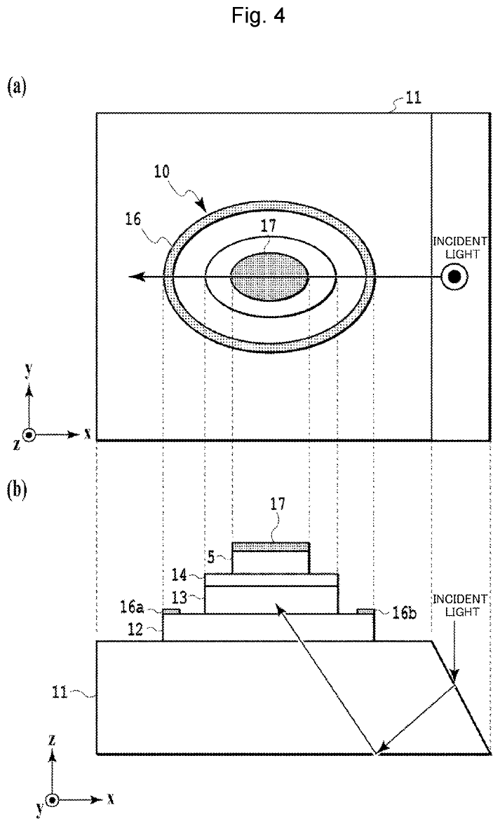

The size of the light receiving element 10 will be described hereinbelow. FIG. 4(a) shows the upper surface of the light receiving element as seen from the z-axis direction, and FIG. 4(b) shows the cross section of the light receiving element corresponding thereto. The effective element size required for the electrode 16 of the first semiconductor layer 12 and the electrode 17 of the second semiconductor layer 15 may be equal to the diameter of the incident beam in the y-axis direction. The shape of the light receiving element 10 may be circular as has been often used in the related art, but is not always needed to be such.

For example, the shape of the light receiving element 10 is not a perfect circle, and the diameter in the optical axis direction connecting the incident point where the incident light enters the oblique surface of the substrate 11, the reflection point where the light is folded back at the bottom surface of the substrate 11, and the light receiving element 10, that is, the x-axis direction, is made larger than the diameter in the y-axis direction. As a result, the optical path length of the incident light can be increased, and the light receiving sensitivity can be improved. The structure may be rectangular or oval obtained by rounding the corners of the rectangle so as not to interfere with the incidence of light, provided that the length in the x-axis direction is larger than the length in the y-axis direction. The latter is advantageous in terms of high-speed response because the size of the light receiving element can be reduced without impairing the light receiving sensitivity.

As shown in FIG. 1, in the semiconductor light receiving element of the first embodiment, since the incident light folds back in the substrate 11, in the case of a material in which the substrate 11 absorbs light, the light intensity is attenuated before the light receiving element 10 is reached. For example, when a high-concentration carrier-doped substrate is used, attenuation of incident light due to free carrier absorption is expected. In order to allow the light receiving element to absorb light with high efficiency, the material of the substrate may be a semi-insulating substrate without carrier doping, for example, semi-insulating InP or the like. Where the carrier doping is small and the resistance value of the substrate is 1 MΩ cm, absorption on the substrate can be substantially suppressed.

### Second Embodiment

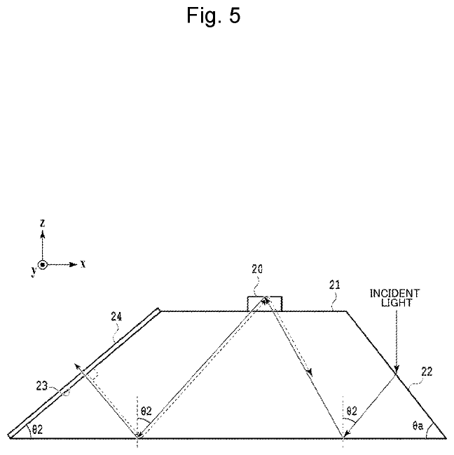

FIG. 5 shows the configuration of the semiconductor light receiving element according to the second embodiment of the present invention. A semiconductor light receiving element 20 is formed on the upper surface of a substrate 21, and the structure thereof is the same as that of the first embodiment. In FIG. 5, the z-axis direction is the semiconductor crystal growth direction. An oblique surface (facet surface) 22 for light incidence is formed on the side surface of the substrate 21. In addition, an oblique surface 23 is also formed on the surface facing the oblique surface 22 in the x-axis direction, and a reflective layer (for example, a metal film formed of Ti and Au) 24 is formed on the oblique surface 23.

The solid line represents the optical path of the incident light. The incident light is incident on the oblique surface 22 of the substrate 21 in parallel with the z-axis, incident on the oblique surface 22, reflected by the bottom surface of the substrate 21, and incident on the light receiving element 20. The light is incident on the light receiving element 20 and folded back by the mirror on the upper surface of the light receiving element 20. The reflected light is once again folded back at the bottom surface of the substrate 21 and incident on the reflective layer 24 on the oblique surface 23. The dotted line represents the optical path after reflection by the reflective layer 24 on the oblique surface 23.

In the cross-sectional view of FIG. 5 (xz plane), the acute angle formed by the oblique surface 23 and the bottom surface of the substrate 21 is set to the same angle of incidence on the light receiving element as θ₂. The light reflected by the reflective layer 24 passes through the same optical path as the optical path represented by the solid line, and is again incident on the light receiving element 20. That is, in the second embodiment, the optical path length in the light receiving element can be doubled as compared with the first embodiment.

### Third Embodiment

In the second embodiment, when the incident light is focused on the light receiving element 20, the beam diameter expands as shown in a propagation formula while the light is reflected by the mirror on the upper surface of the light receiving element 20 and transmitted through the substrate 21 again. The light emitted from the light receiving element 21 folds back at the bottom surface of the substrate 21 at a reflection angle θ₂. The distance L′ from this turning point to the light receiving element 20 is expressed by the following formula.

$${L}^{′} = \frac{( Substrate thickness )}{cos {θ}_{2}} \qquad Math . 6$$

Even if the light receiving element 20 is arranged near the oblique surface 23 on which the reflective layer 24 is formed and the distance between the reflective layer 24 and the turning point on the bottom surface of the substrate 21 is made negligibly small, the beam diameter is expanded due to the propagation of light on the forward-backward segment between the light receiving element 20 and the turning point. Of the light reflected by the reflective layer 24, the component incident on the light receiving element 20 contributes to the light receiving sensitivity, but the light component bypassing the light receiving element 20 does not contribute to the light receiving sensitivity. Where the radius of the light receiving element 20 is increased in consideration of the beam diameter at the time of folding back at the bottom surface of the substrate 21, the light receiving sensitivity can be expected to increase by the optical path length, but the response speed of the light receiving element 20 deteriorates.

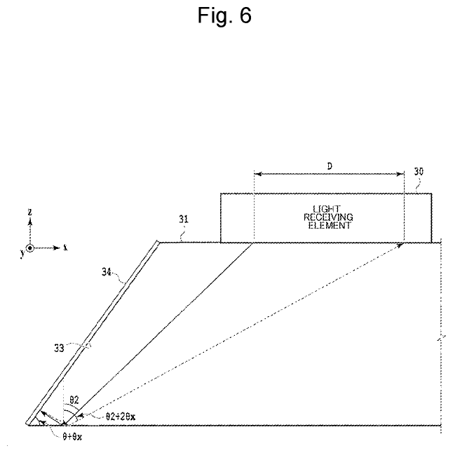

FIG. 6 shows the configuration of the semiconductor light receiving element according to the third embodiment of the present invention. A semiconductor light receiving element 30 is formed on the upper surface of the substrate 31, and the structure thereof is the same as that of the first embodiment. As compared with the second embodiment, a case is considered in which the acute angle formed by an oblique surface 33 on which a reflective layer 34 is formed and the bottom surface of a substrate 31 is slightly deviated from θ₂. The solid line represents the optical path from the light receiving element 30 to a reflective layer 34 on the oblique surface 33, and the dotted line represents the optical path from the reflective layer 34 on the oblique surface 33 to the light receiving element 30. The acute angle formed by the oblique surface 33 and the bottom surface of the substrate 31 is θ₂+θₓ. When the light reflected by the reflective layer 34 of the oblique surface 33 is folded back at the bottom surface of the substrate 31, the reflection angle is θ₂+2θₓ. When the light (dotted line) folded back at the bottom surface of the substrate 31 is incident on the light receiving element 30, the incidence point is located farther from the oblique surface 33 in the x-axis direction than the point of emission from the light receiving element 30.

It is conceivable to use this result and cause the beam expanded by propagation to be incident on the light receiving element 30. Where the oblique surface 33 is brought as close as possible to the position where the light emitted from the light receiving element 30 folds back on the bottom surface of the substrate 31, the point where the light emitted from the light receiving element 30 folds back on the bottom surface of the substrate 31 and the point where the light reflected by the reflective layer 34 folds back can be regarded as almost the same. In this case, the difference D between the position of emission from the light receiving element 30 and the position of re-incident from the reflective layer 34 is

$$D = \frac{( Substrate thickness )}{cos ( {θ}_{2} + 2 {θ}_{x} )} - \frac{( Substrate thickness )}{cos {θ}_{2}} \qquad Math . 7$$

Where D is adjusted to be the difference between the diameter of the propagated beam and the beam waist, the light folded back by the reflective layer 34 can be made fully incident on the light receiving element 30.

After re-incidence on the light receiving element 30, most of the light returned by the mirror on the upper surface of the light receiving element 30 is emitted to the outside of the light receiving element 30. However, even if the light reflected on the upper surface of the light receiving element 30 does not contribute to light reception, in the third embodiment, the optical path length in the light receiving element can be increased by a factor of 1.5 as compared with the first embodiment.

### Fourth Embodiment

In the first to third embodiments, the incident light was incident on the oblique surface of the substrate in parallel with the z-axis, and then reflected on the bottom surface of the substrate. The incident light may be incident obliquely at a desired angle with respect to the vertical direction of the upper surface of the substrate without forming an oblique surface on the side surface of the substrate. After that, the optical path after reflection at the bottom surface of the substrate is the same as in other embodiments.

1. A light receiving element in which a first semiconductor layer composed of a first conductive type semiconductor formed on an upper surface of a substrate, a light absorbing layer composed of a semiconductor, a second semiconductor layer composed of a second conductive type semiconductor, a first electrode formed in contact with the first semiconductor layer, and a second electrode formed in contact with the second semiconductor layer and including a first reflective layer composed of a metal are formed in the order of description in a vertical direction of the upper surface of the substrate,
wherein incident light is incident from the upper surface of the substrate, reflected by the bottom surface of the substrate, and then incident on the light absorbing layer obliquely to the vertical direction.

2. The light receiving element according to claim 1, wherein a first oblique surface is formed on a first side surface of the substrate, and the incident light is incident on the first oblique surface in the vertical direction, refracted by the first oblique surface, and then reflected on the bottom surface of the substrate.

3. The light receiving element according to claim 2, wherein a second oblique surface on which a second reflective layer is formed is formed on a second side surface of the substrate facing the first side surface, and light that has passed through the light absorbing layer and has been reflected by the first reflective layer is reflected by the bottom surface of the substrate, reflected by the second reflective layer, and incident on the light absorbing layer again through the same optical path.

4. The light receiving element according to claim 3, wherein an angle formed by the bottom surface of the substrate and the first oblique surface is different from the angle formed by the bottom surface of the substrate and the second oblique surface.

5. The light receiving element according to claim 1, wherein the shape of the light receiving element when viewed from the vertical direction is such that the length in an optical axis direction connecting an incident point where the incident light enters the substrate and a reflection point where the light is reflected on the bottom surface of the substrate is larger than the length in a direction perpendicular to the optical axis direction.

6. The light receiving element according to claim 1, wherein a resistance of the substrate is 1 MΩ cm or more.

7. The light receiving element according to claim 1, further comprising an avalanche layer composed of a semiconductor between the first semiconductor layer and the second semiconductor layer.
